(19) United States
(12) Patent Application Publication
(10) Pub. No.: US 2025/0385092 A1
(43) Pub. Date: Dec. 18, 2025

(54) MASK STRUCTURE AND MANUFACTURING METHOD THEREFOR, AND SEMICONDUCTOR DEVICE AND MANUFACTURING METHOD THEREFOR

(71) Applicant: SwaySure Technology Co., Ltd., Shenzhen (CN)

(72) Inventor: CHENG-HUNG HSU, Shenzhen (CN)

(21) Appl. No.: 18/980,686

(22) Filed: Dec. 13, 2024

(30) Foreign Application Priority Data
Jun. 13, 2024 (CN) 202410765298.9

(51) Int. Cl. H01L 21/033; H10D 1/00

(52) U.S. Cl. CPC H01L 21/0337; H10D 1/043

(57) ABSTRACT

A manufacturing method for a mask structure includes: forming a stack structure and a photoresist layer located on the stack structure, the photoresist layer including a plurality of photoresist portions distributed at intervals, and each of the plurality of photoresist portions including a first side wall and a second side wall distributed directly facing each other; forming a mask layer on a surface of a structure formed by the stack structure and the plurality of photoresist portions; doping the mask layer; and etching the plurality of photoresist portions and the mask layer to remove the plurality of photoresist portions and form a plurality of openings formed by separating the first portion from the second portion, where when the plurality of photoresist portions and the mask layer are etched, an etching rate of the first portion is different from an etching rate of the second portion.

### CROSS-REFERENCE TO RELATED APPLICATIONS

This application claims priority to Chinese Patent Application 202410765298.9, filed on Jun. 13, 2024, the entire disclosure of which is hereby incorporated herein by reference.

### TECHNICAL FIELD

The present disclosure pertains to the technical field of semiconductors, in particular to a mask structure and a manufacturing method therefor, and a semiconductor device and a manufacturing method therefor.

### BACKGROUND

The memory is widely used in mobile devices such as mobile phones and tablet computers due to its advantages such as small volume, high integration degree and high transmission speed. During a manufacturing process of a memory, corresponding holes need to be formed by means of a mask structure; however, due to the limitation of a manufacturing method for a mask structure, the size of holes finally manufactured by means of the mask structure is relatively small, thereby causing structure defects, and the relatively low product yield.

It should be noted that the information disclosed in the background section above is only for enhancement of understanding of the background of the present disclosure, and therefore may include information that does not form the prior art known to those skilled in the art.

### SUMMARY

There is provided a mask structure and a manufacturing method therefor, and a semiconductor device and a manufacturing method therefor according to embodiments of the present disclosure. The technical solution is as below:

According to a first aspect of the present disclosure, there is provided a manufacturing method for a mask structure, including:
forming a stack structure and a photoresist layer located on the stack structure, where the photoresist layer includes a plurality of photoresist portions distributed at intervals, and each photoresist portion includes a first side wall and a second side wall distributed directly facing each other;
forming a mask layer on a surface of a structure formed by the stack structure and the plurality of photoresist portions;
doping the mask layer, to make a doping concentration of a first portion located on the first side wall in the mask layer is different from a doping concentration of a second portion located on the second side wall in the mask layer; and
etching the plurality of photoresist portions and the mask layer to remove the plurality of photoresist portions and form a plurality of openings formed by separating the first portion from the second portion;
where when the plurality of photoresist portions and the mask layer are etched, an etching rate of the first portion is different from an etching rate of the second portion.

According to a second aspect of the present disclosure, there is provided a manufacturing method for a semiconductor device, including:
forming a stacked film layer on a substrate, the stacked film layer including a sacrificial layer and a support layer stacked in sequence in a vertical direction;
using the manufacturing method for a mask structure according to any one of the above items to form a first mask layer on the stacked film layer, and respectively defining the first portion and the second portion located on both sides of the openings in the first mask layer as a first mask structure and a second mask structure, where the first mask structure and the second mask structure both extend in a first direction and are distributed at intervals in a second direction, a width of the second mask structure is greater than a width of the first mask structure, and the second direction intersects with the first direction;
using the manufacturing method for a mask structure according to any one of the above items to form a second mask layer at a side of the first mask layer away from the substrate, and respectively defining the first portion and the second portion located on both sides of the openings in the second mask layer as a third mask structure and a fourth mask structure, where the third mask structure and the fourth mask structure both extend in the second direction and are distributed at intervals in the first direction, and a width of the fourth mask structure is greater than a width of the third mask structure;
etching the support layer and the sacrificial layer by taking the first mask layer and the second mask layer as masks to form a plurality of capacitor holes distributed at intervals;
removing the first mask layer and the second mask layer and forming a lower electrode layer in the capacitor holes;
removing a portion directly facing an overlapping region of the second mask structure and the fourth mask structure in the support layer to form through holes exposing the sacrificial layer; and
using a wet etching process to remove the sacrificial layer.

According to a third aspect of the present disclosure, there is provided a semiconductor device, which is manufactured by the manufacturing method for a semiconductor device according to any one of the above items.

According to a fourth aspect of the present disclosure, there is provided a mask structure, which is manufactured by using the manufacturing method for a mask structure according to any one of the above items.

It should be understood that the foregoing general description and the following detailed description are exemplary and explanatory only and are not intended to limit the present disclosure.

### BRIEF DESCRIPTION OF DRAWINGS

The accompanying drawings, which are incorporated herein and form a part of the description, illustrate embodiments consistent with the present disclosure and together with the description, serve to explain the principles of the present disclosure. It will be apparent that the drawings described below are only some embodiments of the present disclosure, and other drawings may be obtained from them without creative effort for those of ordinary skill in the art.

FIG. 1 is a flowchart of a manufacturing method for a mask structure according to an embodiment of the present disclosure.

FIG. 2 is a schematic diagram of a stack structure and a photoresist layer in an embodiment of the present disclosure.

FIG. 3 is a schematic diagram of a mask layer in an embodiment of the present disclosure.

FIG. 4 is a schematic diagram of ion implantation in an embodiment of the present disclosure.

FIG. 5 is a schematic diagram of a structure after completion of step S140 in an embodiment of the present disclosure.

FIG. 6 is a schematic diagram of a structure after completion of step S210 in an embodiment of the present disclosure.

FIG. 7 is a schematic diagram of a structure after completion of step S310 in an embodiment of the present disclosure.

FIG. 8 is a flowchart of a manufacturing method for a semiconductor device according to an embodiment of the present disclosure.

FIG. 9 is a schematic diagram of a first mask structure, a second mask structure, a third mask structure and a fourth mask structure according to an embodiment of the present disclosure.

FIG. 10 is a cross-sectional view taken along the dotted line in FIG. 9 according to an embodiment of the present disclosure.

FIG. 11 is a top view of capacitor holes and a support layer according to an embodiment of the present disclosure.

FIG. 12 is a cross-sectional view taken along the dotted line in FIG. 11 according to an embodiment of the present disclosure.

FIG. 13 is a schematic diagram of a structure after completion of step S450 in an embodiment of the present disclosure.

FIG. 14 is a top view after completion of step S450 in an embodiment of the present disclosure.

FIG. 15 is a schematic diagram of a structure after completion of step S510 in an embodiment of the present disclosure.

FIG. 16 is a top view after completion of step S510 in an embodiment of the present disclosure.

FIG. 17 is a top view of a developing region according to an embodiment of the present disclosure.

FIG. 18 is a cross-sectional view taken along the dotted line in FIG. 17 according to an embodiment of the present disclosure.

FIG. 19 is a schematic view of a developing region in another embodiment of the present disclosure.

FIG. 20 is a schematic diagram of a structure after completion of step S460 in an embodiment of the present disclosure.

FIG. 21 is a schematic diagram of a structure after completion of step S470 in an embodiment of the present disclosure.

FIG. 22 is a schematic diagram of a structure after completion of step S610 in an embodiment of the present disclosure.

FIG. 23 is a schematic diagram of a structure after completion of step S620 in an embodiment of the present disclosure.

### DESCRIPTION OF THE EMBODIMENTS

The exemplary embodiments will now be described more fully with reference to the accompanying drawings. However, the example embodiments can be implemented in a variety of forms and should not be construed as being limited to the examples set forth herein. Rather, these embodiments are provided so that the present application will be comprehensive and complete, and the concept of exemplary embodiments will be fully communicated to those skilled in the art. The same reference signs in the drawings denote the same or similar structures, and thus the detailed descriptions thereof will be omitted. In addition, the drawings are only schematic illustrations of the present disclosure, and are not necessarily drawn according to a standard size.

Although relative terms, such as “upper” and “lower”, are used throughout this description to describe the relative relationships of one assembly to the other assembly of the reference signs, these terms are used in this description for convenience only, e.g., according to the direction of the examples depicted in the drawings. It will be understood that if the devices of the reference signs are turned over upside down, the assembly recited as “upper” will become the assembly recited as “lower”. When one structure is “on” the other structure, it may mean that the structure is integrally formed on the other structure, or that this structure is “directly” provided on the other structure, or that this structure is “indirectly” provided on the other structure by means of another structure.

The terms “a”, “an”, “the”, “said”, and “at least one” are used to mean that there are one or more elements/components/etc.; the terms “including” and “having” are used to mean open-ended inclusive and mean that there may be additional elements/components/etc. in addition to the listed elements/components/etc.; and the terms “first”, “second”, “third”, and “fourth”, etc., are used merely as markers, and are not intended to limit the number of objects.

During the manufacturing process of a semiconductor device, a mask structure is usually used; however, the size of holes or openings in a mask structure formed by a conventional mask structure manufacturing method is relatively small, or the distance between the openings is relatively small, such that a process space (holes or openings) is relatively small in a subsequent wet process, and thus structure defects such as incomplete etching may be generated due to limitation of a surface tension of a liquid or bubbles.

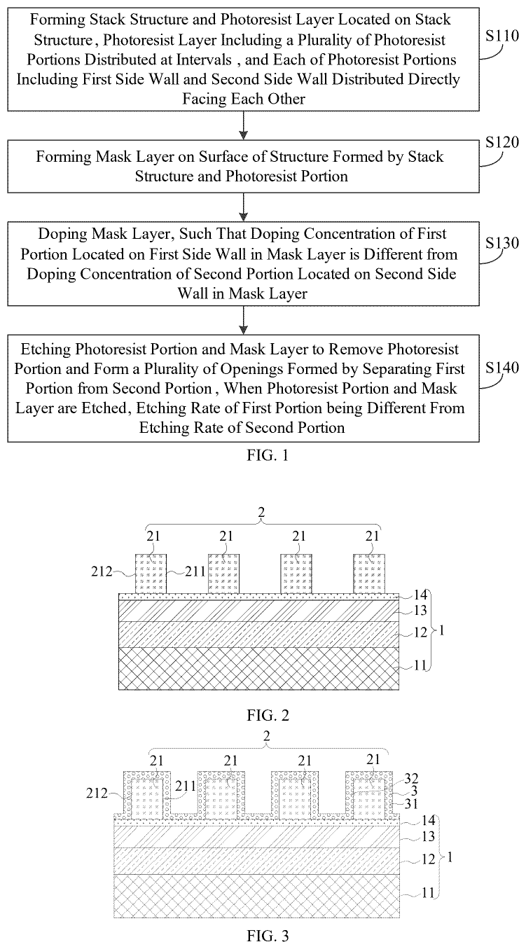

On this basis, an embodiment of the present disclosure provides a manufacturing method for a mask structure. As shown in FIG. 1, the manufacturing method for a mask structure of the present disclosure may include steps S110-S140:
step S110: forming a stack structure and a photoresist layer located on the stack structure, the photoresist layer including a plurality of photoresist portions distributed at intervals, and each photoresist portion includes a first side wall and a second side wall distributed directly facing each other;
steps S120: forming a mask layer on a surface of a structure formed by the stack structure and the plurality of photoresist portions;
steps S130: doping the mask layer, such that the doping concentration of a first portion located on the first side wall in the mask layer is different from the doping concentration of a second portion located on the second side wall in the mask layer; and
step S140: etching the plurality of photoresist portions and the mask layer to remove the plurality of photoresist portions and form a plurality of openings formed by separating the first portion from the second portion, when the plurality of photoresist portions and the mask layer are etched, an etching rate of the first portion is different from an etching rate of the second portion.

In the manufacturing method for the mask structure provided by the present disclosure, by doping a first portion located on the first side wall of the plurality of photoresist portions and a second portion located on the second side wall thereof with different concentrations, the first portion and the second portion exhibit different etching rates during an etching process, and the openings finally formed thereby have different gap sizes; in addition, in the same etching time, a portion having a relatively large etching rate consumes more of the mask layer, has a smaller width, and leaves a larger space for forming the openings, so that the size of the finally formed openings also correspondingly increases; and in a subsequent process of forming holes by using the mask structure, the size of the holes formed by using the openings as a mask pattern is correspondingly increased, reducing structure defects caused by a small size of the holes.

The steps and specific details of the manufacturing method for the mask structure of the present disclosure will be described in detail as follows:
as shown in FIG. 1, the step S110 includes: forming a stack structure and a photoresist layer located on the stack structure, the photoresist layer includes a plurality of photoresist portions distributed at intervals, and each photoresist portion includes a first side wall and a second side wall distributed directly facing each other.

As shown in FIG. 2, the stack structure 1 may include a plurality of film layers, which may include, for example, at least two film layers of a polysilicon layer 11, a silicon oxide layer 12, a spin on carbon layer (SOC) 13, and an anti-reflective layer (Dielectric Anti-Reflective Coating, DARC for short) 14. The photoresist layer 2 may be formed on the surface of the stack structure 1 by spin on or other approaches, and the material of the photoresist layer 2 may be a positive photoresist or a negative photoresist, which is not specifically limited herein. The photoresist layer 2 may be exposed by using a mask plate, and the pattern of the mask plate may match the pattern required by the plurality of photoresist portions 21. Subsequently, the exposed photoresist layer 2 may be developed, so as to form a plurality of photoresist portions 21 distributed at intervals. In an exemplary embodiment of the present disclosure, the plurality of photoresist portions 21 may be in a strip shape, and the plurality of photoresist portions 21 may be distributed at intervals in a direction perpendicular to the extending direction of the plurality of photoresist portions 21. Each photoresist portion 21 may have a first side wall 211 and a second side wall 212 distributed directly facing each other, the surfaces of the first side wall 211 and the second side wall 212 may be flat, and the first side wall 211 and the second side wall 212 may be distributed in parallel.

As shown in FIG. 1, the step S120 includes forming a mask layer 3 on a surface of a structure formed by the stack structure 1 and the plurality of photoresist portions 21.

In an exemplary embodiment of the present disclosure, as shown in FIG. 3, the material of the mask layer 3 may be silicon oxide or polysilicon. The mask layer 3 covering the surface of the structure formed by the stack structure 1 and the plurality of photoresist portions 21 in a conformal manner may be formed by means of atomic layer deposition, physical vapor deposition, chemical vapor deposition, or the like. Of course, the mask layer 3 may also be formed by other approaches. The approach for forming the mask layer 3 is not particularly limited herein.

As shown in FIG. 1, the step S130 includes doping the mask layer 3, such that the doping concentration of a first portion 31 located on the first side wall 211 in the mask layer 3 is different from the doping concentration of a second portion 32 located on the second side wall 212 in the mask layer 3.

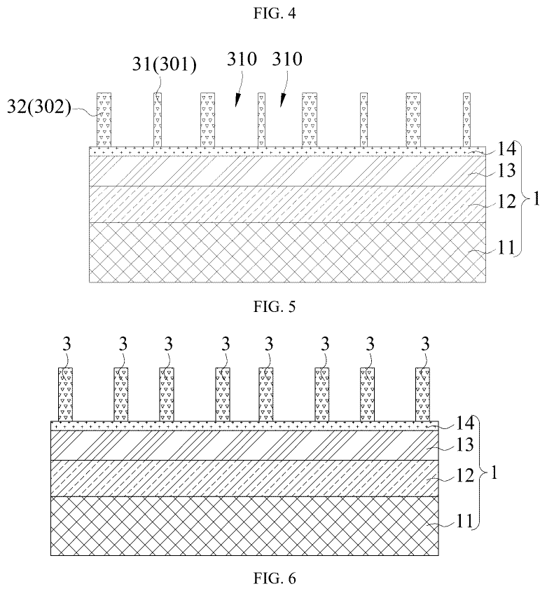

As shown in FIG. 4, ion doping may be performed on the mask layer 3 by an ion implantation process. The doped ions may be elements of Group III or Group V in the periodic table, for example, the doped ions in the mask layer 3 may include one or more of phosphorus ions, boron ions, arsenic ions or gallium ions.

For example, the first portion 31 on the first side wall 211 of the plurality of photoresist portions 21 may be subjected to ion doping at a preset angle on a side close to the first side wall 211 of the plurality of photoresist portions 21 by an ion implantation process, and the preset angle may be an included angle between a normal of the first side wall 211 and the ion beam; and after ion doping, the concentration of the ions in the first portion 31 of the first side wall 211 is greater than the concentration of the ions in the second portion 32 of the second side wall 212. For example, the doping concentration of the second portion 32 on the second side wall 212 may be 0. It should be noted that, ions generated by an ion source in the ion implantation process are accelerated to reach a higher energy by an accelerator, and the energy range may be 10 keV to 900 keV. Further, during the ion implantation process, a machine table may drive the plurality of photoresist portions 21 to rotate reciprocally, and the rotation angle thereof may be between 1° and 89°.

Alternatively, the second portion 32 of the second side wall 212 of the plurality of photoresist portions 21 may be subjected to ion doping at a side close to the second side wall 212 of the plurality of photoresist portions 21 by an ion implantation process at a preset angle, and the preset angle may be an included angle between a normal of the second side wall 212 and the ion beam; and after the ion doping, the ion doping concentration of the second portion 32 on the second side wall 212 is greater than the ion doping concentration of the first portion 31 on the first side wall 211. For example, the doping concentration of the first portion 31 on the first side wall 211 may be 0. It should be noted that, in the ion implantation process, in order to facilitate the process, ion implantation may be performed on the mask layer 3 located on the top of the plurality of photoresist portions 21 at the same time, and/or, ion implantation may also be performed on the mask layer 3 located between two adjacent photoresist portions 21, that is, in order to facilitate the process, other portions of the mask layer 3 other than the first portion 31 and the second portion 32 may also be subjected to ion implantation at the same time.

In some embodiments of the present disclosure, the preset angle can be 5° to 60°, for example, it can be 5°, 10°, 20°, 30°, 40°, 50° or 60°, and of course, other angles can also be possible, which will not be further enumerated here.

As shown in FIG. 1, step S140 includes etching the plurality of photoresist portions 21 and the mask layer 3 to remove the plurality of photoresist portions 21 and form a plurality of openings 310 formed by separating the first portion 31 from the second portion 32, when the plurality of photoresist portions 21 and the mask layer 3 are etched, an etching rate of the first portion 31 is different from an etching rate of the second portion 32.

In the present disclosure, the plurality of photoresist portions 21 and the other portions of the mask layer 3 except the first portion 31 and the second portion 32 can be removed by combining dry etching with wet etching, and the width of the first portion 31 and the width of the second portion 32 can be differentiated. It should be noted that, after the plurality of photoresist portions 21 are removed, the first portion 31 and the second portion 32 originally located at two sides of the plurality of photoresist portions 21 are alternately arranged, and two adjacent first portion 31 and second portion 32 enclose the openings 310. In the embodiments of the present disclosure, the structure after completion of step S140 is shown in FIG. 5.

In an exemplary embodiment of the present disclosure, etching the plurality of photoresist portions 21 and the mask layer 3 to remove the plurality of photoresist portions 21 and form a plurality of openings separated by the first portion 31 and the second portion 32 (i.e. step S140) can include steps S210 and S220:
step S210: using a dry etching process to remove the plurality of photoresist portions 21 and remove other portions except the first portion 31 and the second portion 32 in the mask layer 3.

The mask layer 3 can be etched by using dry etching, as the dry etching is anisotropic etching, other portions (i.e. a mask layer 3 located on the top of the plurality of photoresist portions 21 and between two adjacent photoresist portions 21) except the first portion 31 and the second portion 32 in the mask layer 3 can be removed, and during this process, even if the top of the first portion 31 and the second portion 32 is slightly damaged, the overall profile thereof may not be affected greatly, and thus the first portion 31 and the second portion 32 on both sides of the plurality of photoresist portions 21 can be retained. Taking silicon oxide of the material of the mask layer 3 as an example, the etching gas used in the process of dry etching of the mask layer 3 may be a fluorine-containing gas.

After etching the portions of the mask layer 3 except the first portion 31 and the second portion 32, the etching gas can be changed to perform dry etching on the plurality of photoresist portions 21, and the etching rate of the changed etching gas for the plurality of photoresist portions 21 is far greater than that for the first portion 31 and the second portion 32, that is, the first portion 31 and the second portion 32 are hardly damaged in the process of etching the plurality of photoresist portions 21; for example, during dry etching of the plurality of photoresist portions 21, the etching selectivity ratio of the plurality of photoresist portions 21 to the first portion 31 and the second portion 32 is greater than 100:1. Taking photoresist of the material of the plurality of photoresist portions 21 as an example, the etching gas can be changed to oxygen. That is, the plurality of photoresist portions 21 may be dry-etched by oxygen, and at this time, the oxygen may burn off the plurality of photoresist portions 21. In the embodiments of the present disclosure, the structure after completion of step S210 is shown in FIG. 6.

Step S220: etching the first portion 31 and the second portion 32 by using a wet etching process, in which the wet etching rate of the first portion 31 is different from the wet etching rate of the second portion 32, so that widths of the first portion 31 and the second portion 32 located on two sides of the openings 310 after wet etching are different.

After removing the plurality of photoresist portions 21, the remaining mask layer 3 may be etched by a wet etching process. For example, when the material of the mask layer 3 is silicon oxide, the mask layer 3 can be etched by using an acidic solution, for example, the acidic solution can be dilute hydrofluoric acid (DHF) (the dilution ratio can be 100:1 to 2000:1) or a mixture of dilute sulfuric acid, hydrofluoric acid and hydrogen peroxide. During wet etching, as ion implantation destroys covalent bonds in the mask layer 3, the etching rate of the mask layer 3 at a portion with a large ion doping concentration is accelerated, the etching rate of the mask layer 3 at a portion with a small ion doping concentration or without ion doping is relatively slow, accordingly, after wet etching, the first portion 31 and the second portion 32 exhibit different etching rates, and the finally formed openings 310 have different gap sizes. In addition, in the same etching time, a portion with a relatively large etching rate consumes more of the mask layer 3, has a smaller width, and leaves a large space for the formation of the openings 310, so that the size of the finally formed openings 310 also correspondingly increases, i.e. compared with the prior art, under the same process node, the size of the openings 310 in the present application is greater than the size of the openings 310 in the prior art.

In an exemplary embodiment of the present disclosure, etching the plurality of photoresist portions 21 and the mask layer 3 to remove the plurality of photoresist portions 21 and form a plurality of openings separated by the first portion 31 and the second portion 32 (i.e. step S140) may include steps S310 and S320:
step S310: using the wet etching process to etch the mask layer 3, the wet etching rate of the first portion 31 being different from the wet etching rate of the second portion 32, such that the widths of the remaining first portion 31 and the remaining second portion 32 after the wet etching are different.

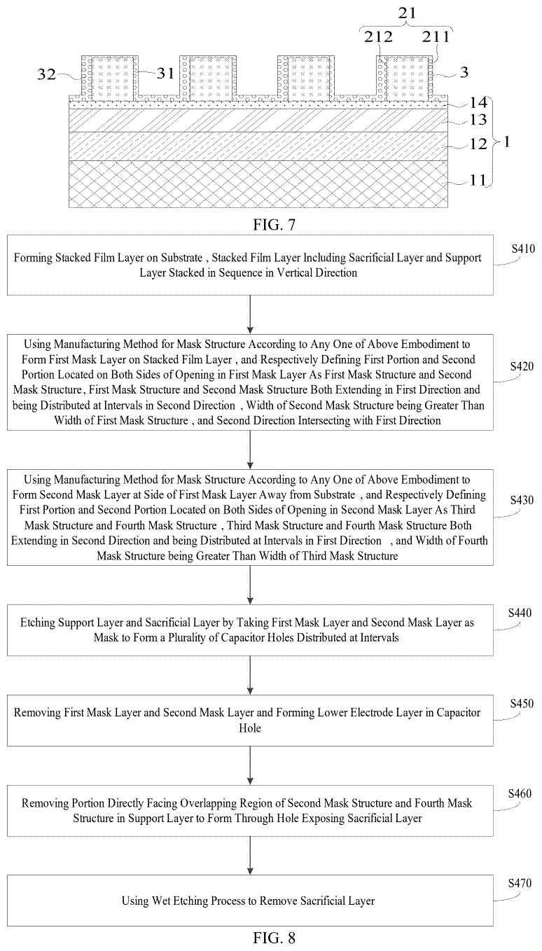

The mask layer 3 can be first etched by a wet etching process, and in this process, as ion implantation destroys covalent bonds in the mask layer 3, the first portion 31 and the second portion 32 exhibit different etching rates; in the same etching time, a portion with a relatively large etching rate consumes more of the mask layer 3 and has a smaller width, so that the width of the remaining first portion 31 and the width of the remaining second portion 32 after wet etching are differentiated (i.e. the width of the first portion 31 is different from the width of the second portion 32). It should be noted that, other details in step S310 (for example, the material of the mask layer 3, a solution used in wet etching) are similar to those in step S220, and therefore are not repeated herein. In the embodiments of the present disclosure, the structure after completion of step S310 is shown in FIG. 7.

Step S320: using a dry etching to remove the plurality of photoresist portions 21 and remove other portions of the mask layer 3 except the first portion 31 and the second portion 32 after wet etching.

After the wet etching, the mask layer 3 (i.e. the portions other than the first portion 31 and the second portion 32 in the mask layer 3) located on the top of the plurality of photoresist portions 21 and between two adjacent photoresist portions 21 may be removed by dry etching. Taking silicon oxide of the material of the mask layer 3 as an example, the etching gas used in the process of dry etching of the mask layer 3 may be a fluorine-containing gas.

After etching the mask layer 3 located on the top of the plurality of photoresist portions 21 and between two adjacent photoresist portions 21, the etching gas can be changed to perform dry etching on the plurality of photoresist portions 21. Taking photoresist of the material of the plurality of photoresist portions 21 as an example, the etching gas can be changed to oxygen. That is, the plurality of photoresist portions 21 may be removed by performing dry etching thereon with oxygen. It should be noted that, other details of step S320 (for example, the etching selection ratio of the plurality of photoresist portions 21 to the first portion 31 and the second portion 32) are similar to those of step S210, and thus are not be repeated herein.

The embodiments of the present disclosure further provide a manufacturing method for a semiconductor device. The manufacturing method for a semiconductor device may include steps S410-S470:
step S410: forming a stacked film layer 200 on a substrate 100, the stacked film layer 200 including a sacrificial layer 201 and a support layer 202 stacked sequentially in a vertical direction;
step S420: forming a first mask layer 300 on the stacked film layer 200 by using the manufacturing method for a mask structure in any one of the above embodiments, and respectively defining the first portion 31 and the second portion 32 located on two sides of the openings 310 in the first mask layer 300 as first mask structure 301 and second mask structure 302, the first mask structure 301 and the second mask structure 302 both extending in a first direction x and being distributed at intervals in a second direction y, the width of the second mask structure 302 being greater than that of the first mask structure 301, and the second direction y intersecting with the first direction x;
step S430: forming a second mask layer 400 on a side of the first mask layer 300 away from the substrate 100 by the manufacturing method for a mask structure in any of the above embodiments, respectively defining the first portion 31 and the second portion 32 of the second mask layer 400 on both sides of the openings 310 as a third mask structure 401 and a fourth mask structure 402, the third mask structure 401 and the fourth mask structure 402 both extending in the second direction y and being distributed at intervals in the first direction x, and the width of the fourth mask structure 402 being greater than the width of the third mask structure 401;
step S440: etching the support layer 202 and the sacrificial layer 201 by taking the first mask layer 300 and the second mask layer 400 as masks to form a plurality of capacitor holes 210 distributed at intervals;
step S450: removing the first mask layer 300 and the second mask layer 400, and forming a lower electrode layer 500 in the capacitor holes 210;
step S460: removing a portion directly facing an overlapping region of the second mask structure 302 and the fourth mask structure 402 in the support layer 202 to form through holes 2001 exposing the sacrificial layer 201;
and step S470: removing the sacrificial layer 201 by using a wet etching process.

In the manufacturing method for a semiconductor device of the present disclosure, as the widths of the second mask structure 302 and the fourth mask structure 402 are relatively large, and the second mask structure 302 overlaps with the fourth mask structure 402, compared with other conditions where the mask structures overlap, the area of a region A where the second mask structure 302 overlaps with the fourth mask structure 402 is relatively large; after the patterns of the first mask layer 300 and the second mask layer 400 are transferred to the stacked film layer 200, the area of the portion of the support layer 202 directly facing the overlapping region A of the second mask structure 302 and the fourth mask structure 402 is relatively large, so that the area of the sacrificial layer 201, exposed after the portion of the support layer 202 directly facing the overlapping region of the second mask structure 302 and the fourth mask structure 402 is removed, is relatively large; and when the sacrificial layer 201 is wet-etched subsequently, a process space (i.e. the holes) of wet etching is relatively large, the liquid tension is relatively small, and bubbles are relatively small. The liquid in the wet etching can sufficiently enter the sacrificial layer 201, which helps to reduce etching residues, reduce defects, and improve the product yield.

The steps of the manufacturing method for a semiconductor device of the present disclosure and the specific details thereof will be described in detail as follows:

as shown in FIG. 8, in step S410, a stacked film layer 200 is formed on a substrate 100, and the stacked film layer 200 includes a sacrificial layer 201 and a support layer 202 sequentially stacked in the vertical direction.

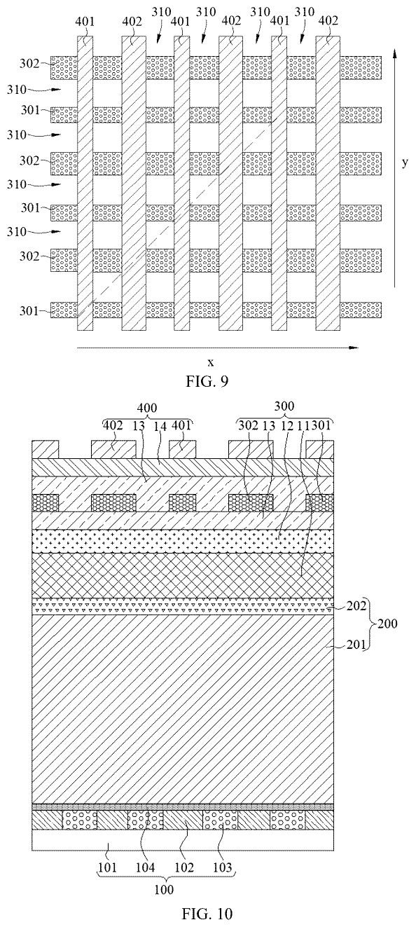

In an exemplary embodiment of the present disclosure, as shown in FIG. 9, the substrate 100 may include a base 101, the base 101 may be of a flat plate structure, and may be rectangular, circular, oval, polygonal or irregular, the material thereof may be silicon or other semiconductor materials, and the shape and material of the base 101 are not specifically limited herein.

In some embodiments of the present disclosure, with continued reference to FIG. 9, the substrate 100 may further include an insulating layer 102, a bottom support layer 104, and a plurality of conductive portions 103 distributed at intervals, and the insulating layer 102 may fill gaps between the conductive portions 103. For example, the insulating layer 102 may be made of an insulating material, for example, silicon oxide, silicon nitride, or silicon dioxide formed by a chemical vapor deposition process using electronic-grade tetraethyl orthosilicate (TEOS). In the present disclosure, the insulating layer 102 may be formed on the surface of the base 101 by means of chemical vapor deposition, physical vapor deposition, atomic layer deposition or the like, a plurality of via holes arranged at intervals can be formed in the insulating layer 102 by means of a hole forming process, and then a conductive material can be deposited in the via holes by means of chemical vapor deposition, physical vapor deposition or atomic layer deposition, etc., so as to form conductive portions 103 in the via holes, and of course, the conductive portions 103 may also be formed by other approaches, which is not specifically limited herein. The material of the conductive portions 103 may be tungsten, titanium, titanium nitride, or the like, and may also be doped polysilicon. The bottom support layer 104 may cover the surfaces of the insulating layer 102 and the conductive portions 103. The material of the bottom support layer 104 may be an insulating material, for example, silicon nitride, silicon carbonitride or silicon boron nitride.

Referring to FIG. 9 again, the stacked film layers 200 may be formed on the surface of the substrate 100 by chemical vapor deposition, physical vapor deposition, atomic layer deposition or the like. For example, a sacrificial layer 201 may be formed on the surface of the substrate 100, and then a support layer 202 may be formed on the surface of the sacrificial layer 201. The material of the sacrificial layer 201 may be silicon oxide, tetraethyl orthosilicate, or the like, and the material of the support layer 202 may be silicon nitride, silicon carbonitride, silicon boron nitride, or the like.

As shown in FIG. 8, in step S420, a first mask layer 300 is formed on the stacked film layer 200 by using the manufacturing method for a mask structure in any one of the above embodiments, the first portion 31 and the second portion 32 in the first mask layer 300 on two sides of the openings 310 are respectively defined as a first mask structure 301 and a second mask structure 302, the first mask structure 301 and the second mask structure 302 both extend in a first direction x and are distributed at intervals a second direction y, the width of the second mask structure 302 is larger than that of the first mask structure 301, for example, the width of the second mask structure 302 can be 1.05 to 1.5 times the width of the first mask structure 301, as an example, the width of the second mask structure 302 may be 1.05, 1.1, 1.2, 1.3, 1.4 or 1.5 times the width of the first mask structure 301.

For example, the stack structure 1 in the manufacturing method for a mask structure in any one of the above embodiments may be formed on the surface of the stacked film layer 200, referring to FIG. 9 and FIG. 10 again, the stack structure 1 herein may include a polysilicon layer 11, a silicon oxide layer 12 and a spin on carbon layer 13 sequentially formed on the stacked film layer 200, and the first portion 31 and the second portion 32, which are finally formed in the manufacturing method for a mask structure in any one of the above embodiments, can be formed on the surface of the spin on carbon layer 13. For the convenience of distinguishing, in the first portion 31 and the second portion 32 finally formed in the manufacturing method for a mask structure in any one of the above embodiments, the portion with a relatively small width may be taken as the first mask structure 301, and the portion with a relatively large width may be taken as the second mask structure 302. Referring to FIG. 9 again, both the first mask structure 301 and the second mask structure 302 may be in a strip shape, and both the first mask structure 301 and the second mask structure 302 may extend in the first direction x and distributed at intervals in the second direction y.

The second direction y may intersect with the first direction x. For example, the second direction y and the first direction x may be perpendicular to each other. It should be noted that, the perpendicularity may be absolute perpendicularity or substantial perpendicularity, and there is inevitably a deviation in a manufacturing process. In the present disclosure, the angle deviation may be caused due to the limitation of the manufacturing process, so that the included angle between the second direction y and the first direction x has a certain deviation, but as long as the angle deviation of the second direction y and the first direction x is within a preset range, it can be considered that the second direction y is perpendicular to the first direction x. For example, the preset range may be 10°, i.e. it can be considered that the second direction y is perpendicular to the first direction x when the included angle between the second direction y and the first direction x is in a range of greater than or equal to 80° and less than or equal to 100°.

It should be noted that, a structure formed by the polysilicon layer 11, the silicon oxide layer 12, the spin on carbon layer 13, the first mask structure 301 and the second mask structure 302 may be used as the first mask layer 300.

As shown in FIG. 8, in step S430, by using the manufacturing method for a mask structure in any of the above embodiments, a second mask layer 400 is formed on a side of the first mask layer 300 away from the substrate 100, the first portion 31 and the second portion 32 of the second mask layer 400 on both sides of the openings 310 are respectively defined as the third mask structure 401 and the fourth mask structure 402, the third mask structure 401 and the fourth mask structure 402 both extend in the second direction y and are distributed at intervals in the first direction x, and the width of the fourth mask structure 402 is greater than the width of the third mask structure 401. For example, the width of the fourth mask structure 402 may be 1.05 to 1.5 times the width of the third mask structure 401, for example, the width of the fourth mask structure 402 may be 1.05, 1.1, 1.2, 1.3, 1.4 or 1.5 times the width of the third mask structure 401.

Referring to FIG. 10 again, the stack structure 1 in the manufacturing method for a mask structure in any one of the above embodiments may be formed on the surface of the first mask layer 300, here, the stack structure 1 may include a spin on carbon layer 13 and an anti-reflective layer 14 sequentially formed on the first mask layer 300, and the first portion 31 and the second portion 32, which are finally formed in the manufacturing method for a mask structure in any one of the above embodiments, may be formed on the surface of the anti-reflective layer 14. For the convenience of distinguishing, in the first portion 31 and the second portion 32 finally formed in the manufacturing method for a mask structure in any one of the above embodiments, the portion with a relatively small width may be taken as the third mask structure 401, and the portion with a relatively large width may be taken as the fourth mask structure 402. Referring to FIG. 9 again, both the third mask structure 401 and the fourth mask structure 402 may be in a strip shape, and both the third mask structure 401 and the fourth mask structure 402 extend in the second direction y and are distributed at intervals in the first direction x. That is, the orthographic projection of the third mask structure 401 on the substrate 100 is overlapped with the orthographic projections of the first mask structure 301 and the second mask structure 302 on the substrate 100. In addition, the orthographic projection of the fourth mask structure 402 on the substrate 100 is also overlapped with the orthographic projections of the first mask structure 301 and the second mask structure 302 on the substrate 100.

As shown in FIG. 8, in step S440, the support layer 202 and the sacrificial layer 201 are etched by using the first mask layer 300 and the second mask layer 400 as masks, so as to form a plurality of capacitor holes 210 distributed at intervals.

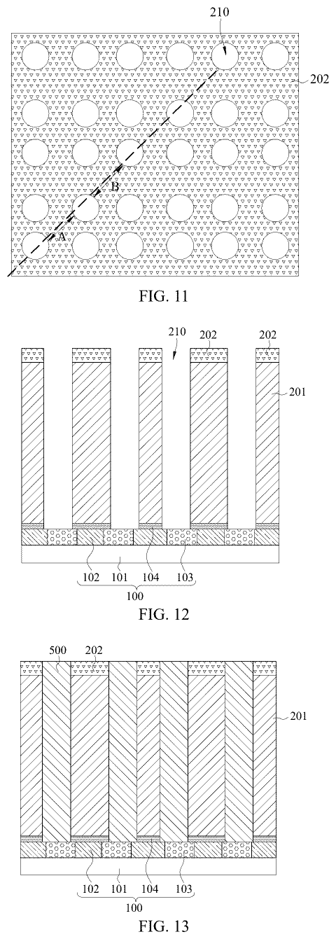

The capacitor holes 210 may be formed by dry etching. In this process, as the orthographic projection of the third mask structure 401 on the substrate 100 is overlapped with the orthographic projections of the first mask structure 301 and the second mask structure 302 on the substrate 100, and the orthogonal projection of the fourth mask structure 402 on the substrate 100 is also overlapped with the orthogonal projections of the first mask structure 301 and the second mask structure 302 on the substrate 100, the first mask structure 301, the second mask structure 302, the third mask structure 401 and the fourth mask structure 402 may define a mesh structure, and when the pattern of the mesh structure is transferred into the stacked film layer 200, a plurality of capacitor holes 210 distributed at intervals can be divided in the stacked film layer 200. As shown in FIG. 11 and FIG. 12, the capacitor holes 210 may penetrate through the support layer 202 and the sacrificial layer 201, and when the substrate 100 of the present disclosure includes the conductive portions 103 and the bottom support layer 104 and the support layer 202 and the sacrificial layer 201 are etched by using the first mask layer 300 and the second mask layer 400 as masks, the bottom support layer 104 may also be etched at the same time, so that the capacitor holes 210 penetrate through the bottom support layer 104 at the same time and expose the conductive portions 103.

It should be noted that, in the process of etching the support layer 202 and the sacrificial layer 201 by using the first mask layer 300 and the second mask layer 400 as masks, due to an actual condition of an etching process, ions may gather on the structure surface around the holes in the etching process, so that the shape of a side wall in contact with the holes changes, and therefore, the finally formed capacitor holes 210 are circular or oval, as shown in FIG. 11.

As shown in FIG. 8, in step S450, the first mask layer 300 and the second mask layer 400 are removed, and a lower electrode layer 500 is formed in the capacitor holes 210.

After forming the capacitor holes 210, the first mask layer 300 and the second mask layer 400 may be removed, so as to expose the surface of the support layer 202. The lower electrode layer 500 may be formed subsequently. The material of the lower electrode layer 500 may be titanium nitride or a composite film layer of titanium and titanium nitride. The lower electrode layer 500 may fill the capacitor holes 210 and be in contact connection with the conductive portions 103. In the embodiments of the present disclosure, the structure after completion of step S450 is shown in FIG. 13. In the embodiments of the present disclosure, the top view after completion of step S450 is as shown in FIG. 14.

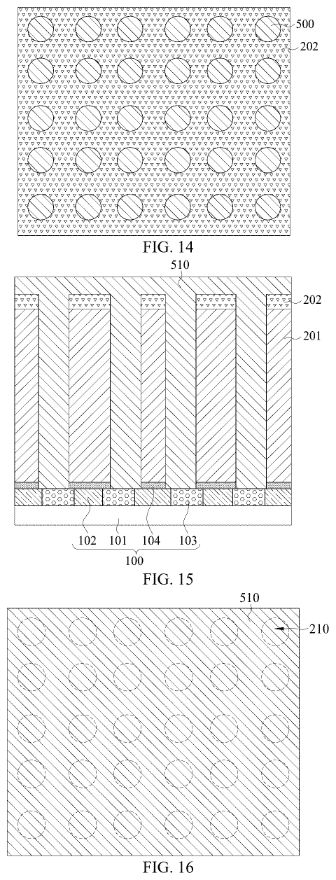

In an exemplary embodiment of the present disclosure, forming the lower electrode layer 500 in the capacitor holes 210 (i.e. step S450) may include step S510 and step S520:
step S510: forming a conductive material layer 510 on a side of the support layer 202 away from the substrate 100, the conductive material layer 510 filling the capacitor holes 210. For example, the material of the conductive material layer 510 may be titanium nitride,
a conductive material may be formed at a side of the support layer 202 away from the substrate 100 by means of chemical vapor deposition, physical vapor deposition, atomic layer deposition, or the like, until the conductive material fills the capacitor holes 210, and the conductive material filling the capacitor holes 210 and a conductive material covering the surface of the support layer 202 may be collectively defined as the conductive material layer 510. In the embodiments of the present disclosure, the structure after completion of step S510 is shown in FIG. 15. In the embodiments of the present disclosure, the top view after completion of step S510 is as shown in FIG. 16.

Step S520: performing planarization processing on the conductive material layer 510 to remove the conductive material layer 510 located on the surface of the support layer 202, flushing a top surface of the conductive material layer 510 in the capacitor holes 210 with a top surface of the support layer 202, and defining the remaining conductive material layer 510 in the capacitor holes 210 as the lower electrode layer 500.

The planarization processing can be performed on the conductive material layer 510 by chemical mechanical planarization (CMP), so as to remove the conductive material layer 510 located on the surface of the support layer 202, and enable the top surface of the conductive material layer 510 located in the capacitor holes 210 to be flush with the top surface of the support layer 202. Of course, the conductive material layer 510 can also be etched back by means of an etch back process, so as to remove the conductive material layer 510 located on the surface of the support layer 202, and enable the top surface of the conductive material layer 510 located in the capacitor holes 210 to be flush with the top surface of the support layer 202. The removal method of the conductive material layer 510 is not particularly limited herein.

As shown in FIG. 8, in step S460, a portion directly facing an overlapping region of the second mask structure 302 and the fourth mask structure 402 in the support layer 202 is removed to form through holes 2001 exposing the sacrificial layer 201.

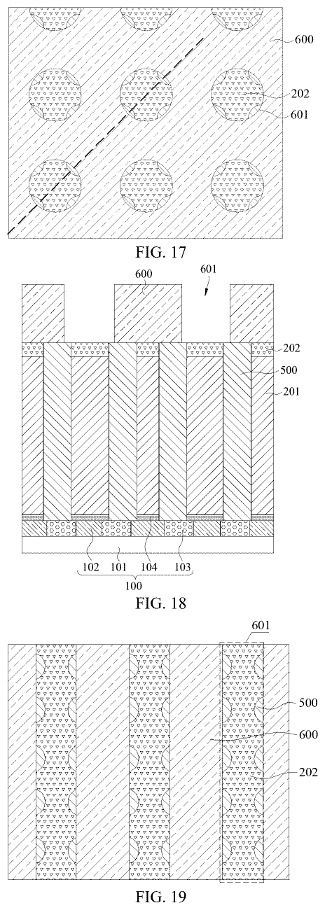

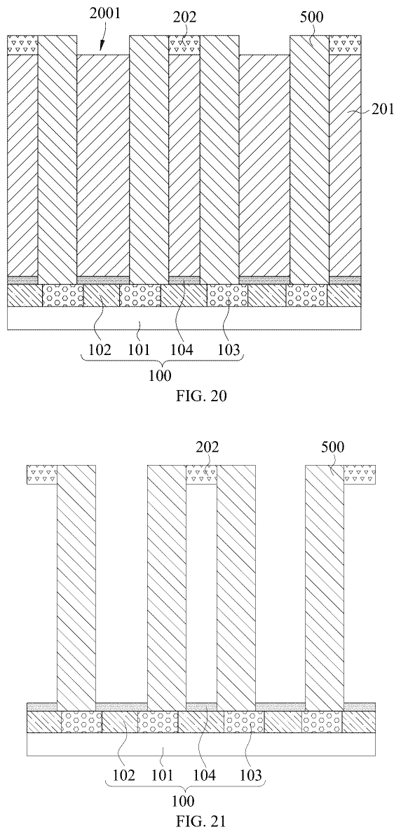

As shown in FIG. 17 and FIG. 18, a photoresist layer 600 may be formed on a surface of a structure formed by the support layer 202 and the lower electrode layer 500 by means of spin on or other approaches, the photoresist layer 600 may be exposed and developed by using a mask plate, so as to form a developing region 601, and as shown in FIG. 18 and FIG. 19, the developing region 601 may expose a portion directly facing an overlapping region of the second mask structure 302 and the fourth mask structure 402 in the support layer 202. The support layer 202 may be etched in the developing region 601 to form through holes 2001 exposing the sacrificial layer 201. In this process, as the region B (as shown in FIG. 11) where the second mask structure 302 overlaps with the fourth mask structure 402 has a relatively large area (for example, the width of the region B is larger than that of the region A), after the patterns of the first mask layer 300 and the second mask layer 400 are transferred to the stacked film layer 200, the area of the portion directly facing the region B where the second mask structure 302 overlaps with the fourth mask structure 402 in the support layer 202 is relatively large, so that the area of the sacrificial layer 201 exposed by the through holes 2001, which are formed by removing the portion directly facing the region where the second mask structure 302 overlaps with the fourth mask structure 402 in the support layer 202, is relatively large. In the embodiments of the present disclosure, the structure after completion of step S460 is shown in FIG. 20.

As shown in FIG. 8, in step S470, the sacrificial layer 201 is removed by using a wet etching process.

The sacrificial layer 201 can be removed by a wet etching process using an acidic solution. When the sacrificial layer 201 is wet etched, the exposed area of the sacrificial layer 201 is relatively large, so that the process space (i.e. the holes) of the wet etching is relatively large, the liquid tension is relatively small, and the bubbles are relatively small. The liquid in the wet etching can fully enter the sacrificial layer 201, which helps to reduce etching residues, reduce defects and improve the product yield. In the embodiments of the present disclosure, the structure after completion of step S470 is shown in FIG. 21.

In an exemplary embodiment of the present disclosure, after the sacrificial layer 201 is removed, the manufacturing method for a semiconductor device of the present disclosure can further includes step S610 and step S620:
step S610: forming a capacitor dielectric layer 700 covering a surface of a structure formed by the substrate 100, the lower electrode layer 500, and the support layer 202 in a conformal manner.

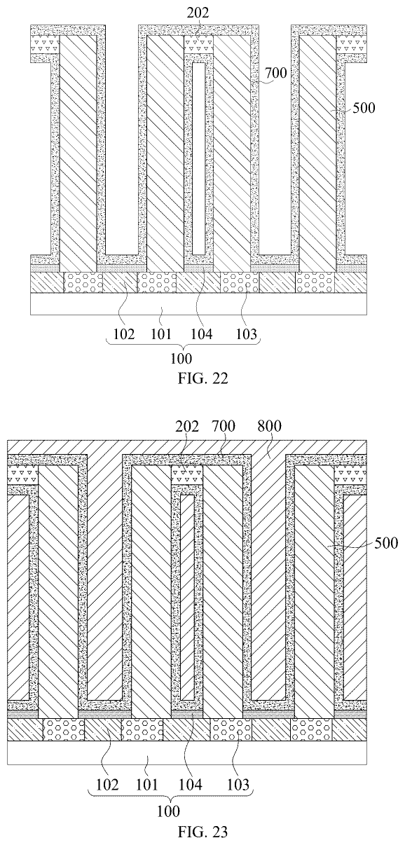

The material of the capacitor dielectric layer 700 can be an insulating material having a high dielectric constant, for example, aluminum oxide, hafnium oxide, lanthanum oxide, titanium oxide, zirconium oxide, tantalum oxide, niobium oxide, strontium oxide or a mixture thereof, and of course, it can also be other materials having a high dielectric constant, which will not be enumerated herein. The capacitor dielectric layer 700 can be formed by means of chemical vapor deposition, physical vapor deposition or atomic layer deposition, etc., and the capacitor dielectric layer 700 can cover the outer surface and the inner surface of the structure formed by the substrate 100, the lower electrode layer 500 and the support layer 202 in a conformal manner. In the embodiments of the present disclosure, the structure after completion of step S610 is shown in FIG. 22.

Step S620: forming an upper electrode layer 800 on a surface of the capacitor dielectric layer 700.

The material of the upper electrode layer 800 may be titanium nitride or a composite film layer of titanium and titanium nitride. The upper electrode layer 800 may cover the surface of the capacitor dielectric layer 700 in a conformal manner, and may also fill the remaining space in the structure, which is not specifically limited herein. The upper electrode layer 800, the capacitor dielectric layer 700, and the lower electrode layer 500 may together form a complete capacitor. In the embodiments of the present disclosure, the structure after completion of step S620 is shown in FIG. 23.

It should be noted that, although the respective steps of the manufacturing method for a mask structure and the manufacturing method for a semiconductor device in the present disclosure are described in a specific sequence in the drawings, it is not required or implied that these steps must be executed in the specific sequence, or all the steps shown must be executed to achieve the desired result. Additionally or alternatively, certain steps may be omitted, multiple steps may be combined into one step for execution, and/or one step may be separated into multiple steps for execution, etc.

The embodiments of the present disclosure further provide a semiconductor device. The semiconductor device may be manufactured by using the manufacturing method for a semiconductor device in any one of the above embodiments. Specific details, forming processes and beneficial effects of the semiconductor device are described in detail in the embodiments of the corresponding manufacturing method for a semiconductor device, and will not be repeated herein.

For example, the semiconductor device may be a junction field-effect transistor (JFET), a dynamic random access memory (DRAM), a static random access memory (SRAM), etc. Of course, the semiconductor device may be other storage devices, which will not be enumerated here.

The embodiments of the present disclosure further provide a mask structure. The mask structure may be manufactured by using the manufacturing method for a mask structure in any one of the above embodiments. Specific details, forming processes and beneficial effects thereof are described in detail in the embodiments of the corresponding manufacturing method for a mask structure, and will not be repeated herein.

Other embodiments of the disclosure will be readily occurred to those skilled in the art from consideration of the description and practice of the invention disclosed herein. The present disclosure is intended to cover any variations, uses or adaptations of the present disclosure, and these variations, uses or adaptations follow the general principles of the present disclosure and include common general knowledge or customary technical means in the art that are not disclosed in the present disclosure. It is intended that the description and embodiments be considered as exemplary only, with a true scope and spirit of the present disclosure being indicated by the following claims.

What is claimed is:

1. A manufacturing method for a mask structure, comprising:
forming a stack structure and a photoresist layer located on the stack structure, wherein the photoresist layer comprises a plurality of photoresist portions distributed at intervals, and each photoresist portion comprises a first side wall and a second side wall distributed directly facing each other;
forming a mask layer on a surface of a structure formed by the stack structure and the plurality of photoresist portions;
doping the mask layer, to make a doping concentration of a first portion located on the first side wall in the mask layer is different from a doping concentration of a second portion located on the second side wall in the mask layer; and
etching the plurality of photoresist portions and the mask layer to remove the plurality of photoresist portions and form a plurality of openings formed by separating the first portion from the second portion;
wherein when the plurality of photoresist portions and the mask layer are etched, an etching rate of the first portion is different from an etching rate of the second portion.

2. The manufacturing method for the mask structure according to claim 1, wherein doping the mask layer comprises:
performing ion doping on the mask layer at a preset angle, wherein the preset angle is an included angle between a normal of the first side wall or a normal of the second side wall and an ion beam, and the preset angle is 5-60°.

3. The manufacturing method for the mask structure according to claim 1, wherein etching the plurality of photoresist portions and the mask layer to remove the plurality of photoresist portions and form the plurality of openings formed by separating the first portion from the second portion comprises:
using a dry etching process to remove the plurality of photoresist portions and remove other portions except the first portion and the second portion in the mask layer; and
using a wet etching process to etch the first portion and the second portion, wherein a wet etching rate of the first portion is different from a wet etching rate of the second portion, such that widths of the first portion and the second portion located on both sides of the plurality of openings are different after the wet etching process.

4. The manufacturing method for the mask structure according to claim 3, wherein a material of the mask layer is silicon oxide, and an etching solution of the wet etching process is an acidic solution;
when other portions except the first portion and the second portion in the mask layer are removed, a fluorine-containing gas is used as an etching gas; and
when the plurality of photoresist portions are removed, oxygen is used as the etching gas.

5. The manufacturing method for the mask structure according to claim 1, wherein etching the plurality of photoresist portions and the mask layer to remove the plurality of photoresist portions and form the plurality of openings formed by separating the first portion from the second portion comprises:
using a wet etching process to etch the mask layer, wherein a wet etching rate of the first portion is different from a wet etching rate of the second portion, such that widths of a remaining first portion and a remaining second portion are different after the wet etching process; and
using a dry etching process to remove the plurality of photoresist portions and remove other portions except the first portion and the second portion in the mask layer after the wet etching process.

6. The manufacturing method for the mask structure according to claim 5, wherein a material of the mask layer is silicon oxide, and an etching solution of the wet etching process is an acidic solution;
when other portions except the first portion and the second portion in the mask layer are removed, a fluorine-containing gas is used as an etching gas; and
when the plurality of photoresist portions are removed, oxygen is used as the etching gas.

7. The manufacturing method for the mask structure according to claim 1, wherein ions doped in the mask layer comprise one or more of phosphorus ions, boron ions, arsenic ions or gallium ions.

8. The manufacturing method for the mask structure according to claim 1, wherein the doping concentration of the first portion is 0.

9. A manufacturing method for a semiconductor device, comprising:
forming a stacked film layer on a substrate, wherein the stacked film layer comprises a sacrificial layer and a support layer stacked in sequence in a vertical direction;
using a mask structure manufacturing method to form a first mask layer on the stacked film layer, and respectively defining the first portion and the second portion located on both sides of the plurality of openings in the first mask layer as a first mask structure and a second mask structure, wherein the first mask structure and the second mask structure extend in a first direction and are distributed at intervals in a second direction, a width of the second mask structure is greater than a width of the first mask structure, and the second direction intersects with the first direction;
using the mask structure manufacturing method to form a second mask layer at a side of the first mask layer away from the substrate, and respectively defining the first portion and the second portion located on both sides of the plurality of openings in the second mask layer as a third mask structure and a fourth mask structure, wherein the third mask structure and the fourth mask structure both extend in the second direction and are distributed at intervals in the first direction, and a width of the fourth mask structure is greater than a width of the third mask structure;
etching the support layer and the sacrificial layer by taking the first mask layer and the second mask layer as masks to form a plurality of capacitor holes distributed at intervals;
removing the first mask layer and the second mask layer, and forming a lower electrode layer in the plurality of capacitor holes;
removing a portion directly facing an overlapping region of the second mask structure and the fourth mask structure in the support layer to form through holes exposing the sacrificial layer; and
using a wet etching process to remove the sacrificial layer;
wherein the mask structure manufacturing method is the manufacturing method for the mask structure of claim 1.

10. The manufacturing method for the semiconductor device according to claim 9, wherein forming the lower electrode layer in the plurality of capacitor holes comprises:
forming a conductive material layer at a side of the support layer away from the substrate, wherein the conductive material layer fills the plurality of capacitor holes; and
performing planarization processing on the conductive material layer to remove the conductive material layer located on the surface of the support layer, flushing a top surface of the conductive material layer in the plurality of capacitor holes with a top surface of the support layer, and defining a remaining conductive material layer in the plurality of capacitor holes as the lower electrode layer.

11. The manufacturing method for the semiconductor device according to claim 10, wherein after removing the sacrificial layer, the manufacturing method for the semiconductor device further comprises:
forming a capacitor dielectric layer covering a surface of a structure formed by the substrate, the lower electrode layer, and the support layer in a conformal manner; and
forming an upper electrode layer on a surface of the capacitor dielectric layer.

12. The manufacturing method for the semiconductor device according to claim 10, wherein the substrate comprises an insulating layer, a bottom support layer, and a plurality of conductive portions distributed at intervals, wherein the insulating layer fills gaps among the plurality of conductive portions; the bottom support layer covers surfaces of the insulating layer and the plurality of conductive portions, and the bottom support layer is etched when the support layer and the sacrificial layer are etched by taking the first mask layer and the second mask layer as the masks, such that the plurality of capacitor holes penetrate through the bottom support layer at the same time and the plurality of conductive portions are exposed; and the lower electrode layer is in contact connection with the plurality of conductive portions.

13. A semiconductor device, wherein the semiconductor device is manufactured by using the manufacturing method for the semiconductor device according to claim 9.

14. A mask structure, wherein the mask structure is manufactured by using the manufacturing method for the mask structure according to claim 1.
